(19) United States
(12) Patent Application Publication
(10) Pub. No.: US 2023/0037606 A1
(43) Pub. Date: Feb. 9, 2023

(54) FIELD EFFECT TRANSISTOR AND METHOD OF MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Jun SAITO, Nisshin-shi (JP); Masatoshi TSUJIMURA, Nisshin-shi (JP)

(21) Appl. No.: 17/880,139

(22) Filed: Aug. 3, 2022

(30) Foreign Application Priority Data
Aug. 5, 2021 (JP) 2021-128887

(51) Int. Cl. H01L 29/78; H01L 29/10; H01L 29/423

(52) U.S. Cl. CPC H01L 29/7813; H01L 29/1095; H01L 29/4236

(57) ABSTRACT

A field effect transistor includes a semiconductor substrate and multiple trenches disposed at a top surface of the semiconductor substrate. The trenches extend in a first direction at the top surface of the semiconductor substrate, and are disposed to be spaced apart in a direction perpendicular to the first direction. Connection regions are disposed below body regions. The connection regions extend in a second direction intersecting the first direction in a top view of the semiconductor substrate, and are spaced apart in a direction perpendicular to the second direction. Field relaxation regions are disposed below the connection regions and the trenches. The field relaxation regions extend in a third direction intersecting the first direction and the second direction in the top view of the semiconductor substrate, and are spaced apart in a direction perpendicular to the third direction.

### CROSS REFERENCE TO RELATED APPLICATION

This application is based on Japanese Patent Application No. 2021-128887 filed on Aug. 5, 2021, the disclosure of which is incorporated herein by reference.

### TECHNICAL FIELD

The present disclosure relates to a field effect transistor, and relates to a method of manufacturing the field effect transistor.

### BACKGROUND

Afield effect transistor may include one or more trench-type gate electrodes, and may further include multiple body regions, multiple connection regions and multiple field relaxation regions. Each of the body regions may be a p-type region, and may be arranged in an inter-trench semiconductor region located between adjacent trenches in the field effect transistor. Each of the body regions may be in contact with a gate insulation film at a side surface of the trench. An n-type drift region may be in contact with the body region at the bottom of the body region.

### SUMMARY

The present disclosure describes a field effect transistor including a semiconductor substrate having connection regions and contact regions, and further describes a method of manufacturing the field effect transistor.

### BRIEF DESCRIPTION OF DRAWINGS

Objects, features and advantages of the present disclosure will become more apparent from the following detailed description made with reference to the accompanying drawings. In the drawings:

FIG. 1 illustrates a cross-sectional perspective view of a metal-oxide-semiconductor field-effect transistor (MOSFET) according to an embodiment, and further illustrates a top surface of a semiconductor substrate, a cross section of a semiconductor substrate of the MOSFET along xz plane, and a cross section of the semiconductor substrate along yz plane;

FIG. 2 illustrates a plan view of the top surface of the semiconductor substrate of the MOSFET according to the embodiment;

FIG. 3 illustrates a cross-sectional view of the MOSFET according to the embodiment along xz plane taken on a line III-III of FIG. 2;

FIG. 4 illustrates a cross-sectional view of the MOSFET according to the embodiment along xz plane taken on a line IV-IV of FIG. 2;

FIG. 5 illustrates a cross-sectional view of the MOSFET according to the embodiment along yz plane taken on a line V-V of FIG. 2; FIG. 6 illustrates a cross-sectional view of the MOSFET according to the embodiment along yz plane taken on a line VI-VI of FIG. 2;

FIG. 7 illustrates a cross-sectional perspective view of the MOSFET according to the embodiment, and further illustrates a cross-section of a region of the MOSFET including a connection region along xy plane, a cross section of the MOSFET along xz plane, and a cross section of the MOSFET along yz plane;

FIG. 8 illustrates a plan view of an arrangement of the trench, the connection region and a field relaxation region in a top view of the semiconductor substrate;

FIG. 9 illustrates a channel and a current path taken on FIG. 3;

FIG. 10 illustrates a plan view of a MOSFET according to a comparative example that corresponds to FIG. 2;

FIG. 11 illustrates a method of manufacturing the MOSFET according to the embodiment;

FIG. 12 illustrates a plan view of a MOSFET according to a first modification that is modified from the MOSFET illustrated in FIG. 8;

FIG. 13 illustrates a plan view of a MOSFET according to a second modification that is modified from the MOSFET illustrated in FIG. 8;

FIG. 14 illustrates a plan view of a MOSFET according to a third modification that is modified from the MOSFET illustrated in FIG. 3;

FIG. 15 illustrates a cross-sectional view of a MOSFET according to a comparative example; and

FIG. 16 illustrates a plan view of the MOSFET according to the comparative example.

### DETAILED DESCRIPTION

When a field effect transistor is turned on, a channel is formed at a region adjacent to a gate insulation film of each of body regions, and the channel is connected to a drift region. Each of connection regions in the field effect transistor may be a p-type region protruded downward from the corresponding body region. Each of the connection regions may extend along the trench. Each of the connection regions may be arranged at a position separated from each of the trenches. Each of field relaxation regions in the field effect transistor may be a p-type region arranged below each of the connection regions. Each of the field relaxation regions may be arranged below a trench-type gate electrode in the field effect transistor, and may extend in a direction intersecting the trench-type gate electrode. Each of the field relaxation regions may be connected to the body region through the connection region. As a result, the potential of each of field relaxation regions may be stabilized.

When the field effect transistor is turned off, a depletion layer spreads from each of the field relaxation regions to its surroundings. The depletion layer spreading from each of the field relaxation regions may relieve an electrical field applied to the gate insulation film near the bottom end of each of the trenches. Therefore, this field effect transistor may have a higher breakdown voltage.

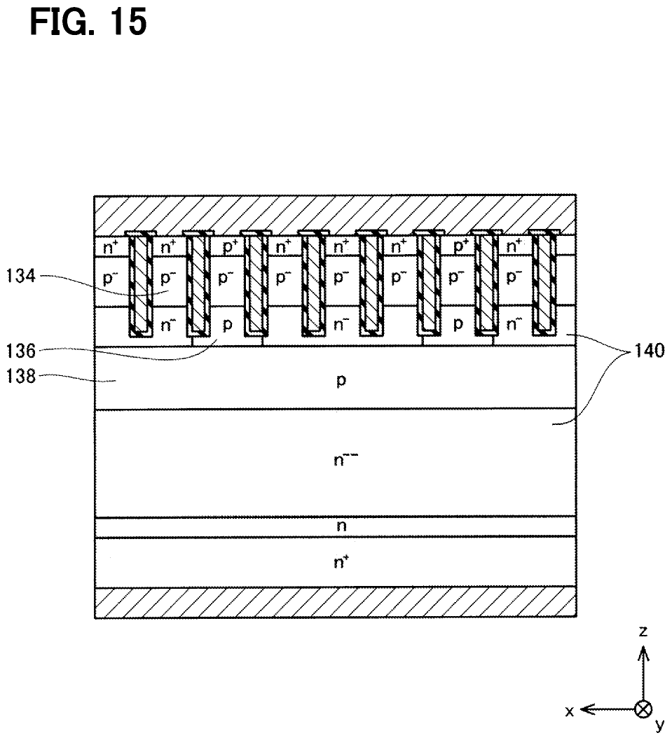

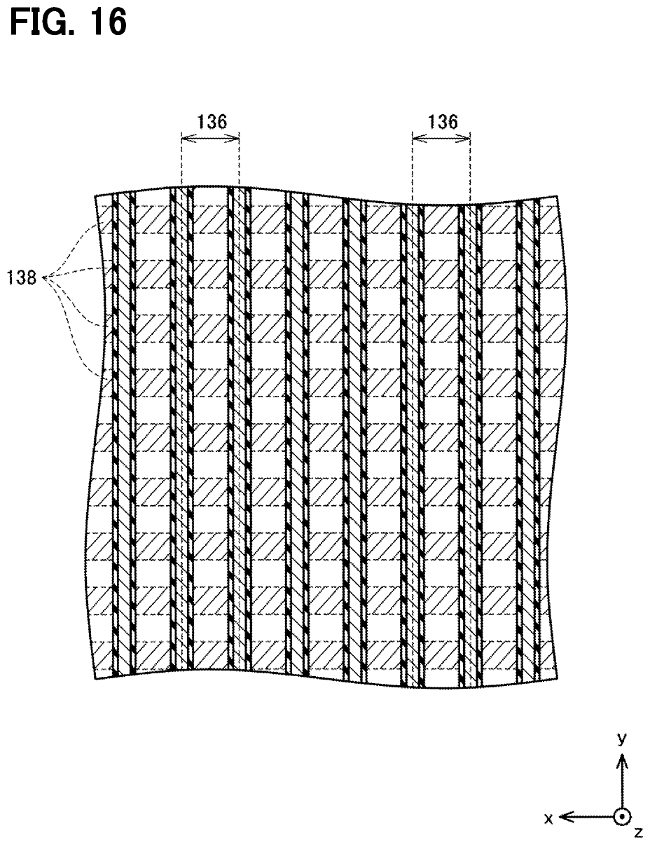

For enhancing channel density, the trench-type gate electrodes are formed at a higher density. In other words, spacing between the trench-type gate electrodes is narrow. When the spacing between the trench-type gate electrodes is narrowed to the limit of machining precision, as illustrated in FIGS. 15, 16, each of connection regions 136 is in contact with a trench, in other words, a gate insulation film. Each of FIGS. 15, 16 illustrates a body region 134, a field relaxation region 138 and a drift region 140. In the structure illustrated in FIGS. 15, 16, a channel formed at the body region is not connected to a drift region in an inter-trench semiconductor region having the connection region. In other words, a current does not flow in a region where the inter-trench semiconductor region is provided. In FIGS. 15, 16, for ensuring the region where the current flows, the connection region is provided only a part of the inter-trench semiconductor regions. In FIGS. 15, 16, with regard to the field effect transistor at an on state, the current does not flow through the entire inter-trench semiconductor region provided with the connection region. Therefore, the current is concentrated in the inter-trench semiconductor region adjacent to the inter-trench semiconductor region provided with the connection region. In the field effect transistor illustrated in each of FIGS. 15, 16, the allowable amount of current that can be conducted is relatively low.

According to a first aspect of the present disclosure, a field effect transistor includes a semiconductor substrate, trenches, a gate insulation film, a gate electrode and a source electrode. The trenches are disposed at a top surface of the semiconductor substrate. The gate insulation film is disposed in each of the trenches. The gate electrode is disposed in each of the trenches. The source electrode covers the top surface of the semiconductor substrate. The trenches respectively extend in a first direction at the top surface, and the trenches are spaced part in a direction perpendicular to the first direction. The semiconductor substrate includes a plurality of inter-trench semiconductor regions, and each of the inter-trench semiconductor regions is disposed between adjacent two of the trenches. The inter-trench semiconductor regions respectively include source regions, contact regions, and body regions. Each of the source regions is an n-type in contact with the source electrode and the gate insulation film. Each of the contact regions is a p-type in contact with the source electrode. Each of the body regions is the p-type that has lower p-type impurity concentration than each of the contact regions, and that is in contact with the gate insulation film at a side closer to a bottom surface of the semiconductor substrate than the source regions, and is in contact with corresponding one of the contact regions and corresponding one of the source regions at a side closer to the bottom surface of the semiconductor substrate than the contact regions and the source regions. The semiconductor substrate includes connection regions respectively being p-type, field relaxation regions respectively being p-type, and a drift region being the n-type. The connection regions are disposed at a side closer to the bottom surface of the semiconductor substrate than the body regions. The connection regions respectively extend in a second direction intersecting the first direction in a top view of the semiconductor substrate, and are disposed to be spaced apart in a direction perpendicular to the second direction in the top view of the semiconductor substrate. The connection regions are connected to the body regions at intersecting portions where the connection regions respectively intersect the body regions. The field relaxation regions are disposed at a side closer to the bottom surface of the semiconductor substrate than the connection regions and the trenches. The field relaxation regions extend in a third direction intersecting the first direction and the second direction in the top view of the semiconductor substrate, and are disposed to be spaced apart in a direction perpendicular to the third direction in the top view of the semiconductor substrate. The field relaxation regions are connected to the connection regions at intersecting portions where the field relaxation regions respectively intersect the connection regions. The drift region is disposed at a first spacing portion between adjacent two of the connection regions, a second spacing portion between adjacent two of the field relaxation regions, and a location at a side closer to the bottom surface of the semiconductor substrate than the field relaxation regions. The drift region is in contact with the body regions at a side closer to the bottom surface of the semiconductor substrate than the body regions, and is in contact with the gate insulation film at a side closer to the bottom surface of the semiconductor substrate than the gate insulation film.

The field relaxation region may partially overlap the connection regions and the trenches in a depth direction. In other words, at least one of the field relaxation regions is arranged below the connection regions, and at least one of the field relaxation regions is arranged below the trenches.

In this field effect transistor, each of the connection regions extends in the second direction intersecting the first direction and the third direction. Each of the trenches extends in the first direction. Each of the field relaxation regions extends in the third direction. The connection regions are connected to the field relaxation regions at intersecting portions where the connection regions respectively intersect the field relaxation regions. Additionally, the connection regions are connected to the body regions at intersecting portions where the connection regions respectively intersect the body regions. Therefore, the field relaxation regions are connected to the body regions through the connection regions. As a result, the potential of each of the field relaxation regions is stabilized. When the field effect transistor is turned on, a channel is not connected to the drift region and a current does not flow at an intersecting portion where the connection region intersects the trench. Since the field relaxation regions extend in a direction intersecting the trenches, intersecting portions where the field relaxation regions respectively intersect the trenches are scattered over the trenches. As a result, it is possible to inhibit the concentration of current flowing through the specific inter-trench semiconductor region. According to the field effect transistor described above, it is possible to inhibit the concentration of current.

According to a second aspect of the present disclosure, a method for manufacturing the field effect transistor described above includes injection of p-type impurities to the contact regions and the connection regions through a common mask.

According to the method described above, it is possible to manufacture the field effect transistor efficiently.

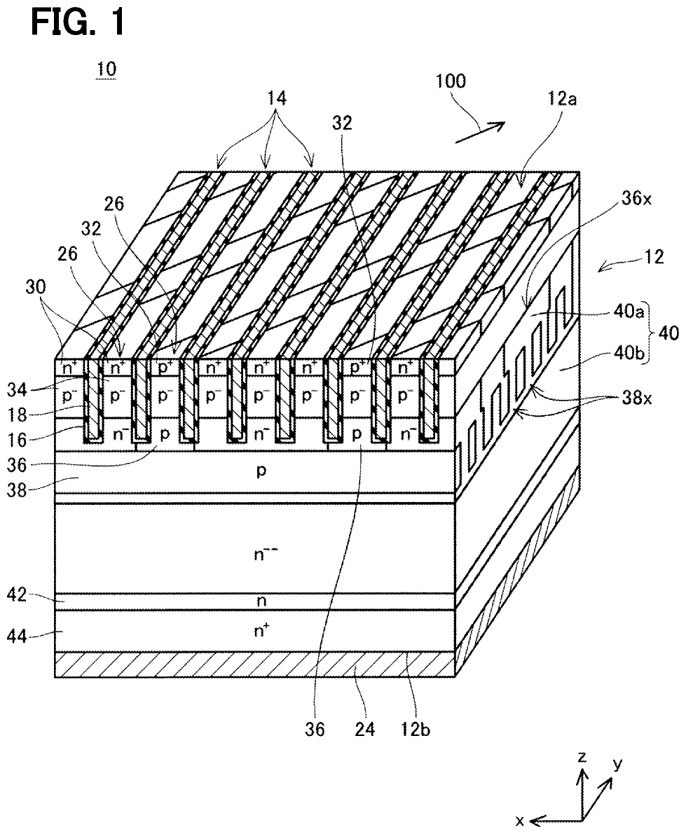

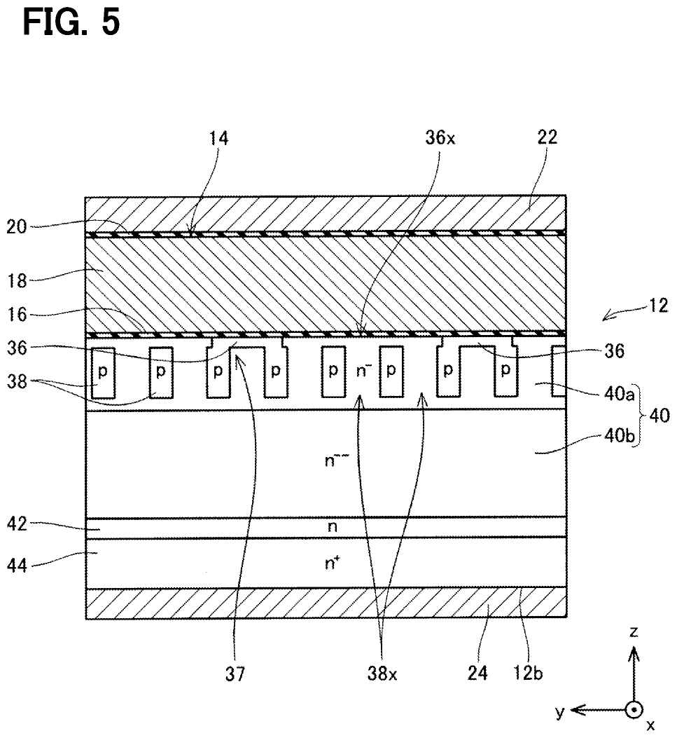

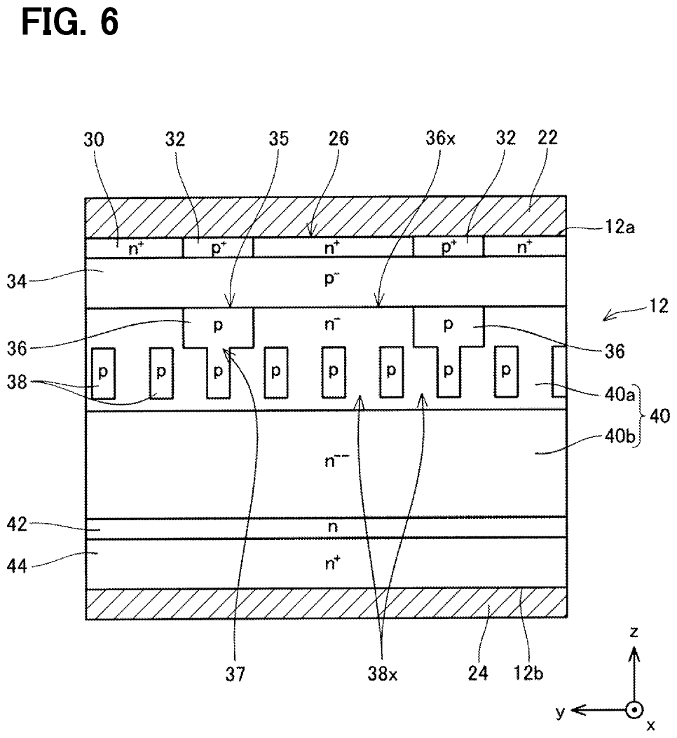

The following describes a metal-oxide-semiconductor field effect transistor (MOSFET) 10 according to an embodiment with reference to FIGS. 1 to 5. The MOSFET 10 may also be simply referred to as a field effect transistor. In the following, a direction parallel to a top surface 12a of a semiconductor substrate 12 may also be referred to as an x-direction, a thickness direction of the semiconductor substrate 12 may also be referred to as a z-direction, and a direction perpendicular to the x-direction and the z-direction may also be referred to as a y-direction. The semiconductor substrate 12 is made of silicon carbide (SiC). However, the semiconductor substrate 12 may also be made of other material such as silicon or gallium nitride. FIG. 1 omits the illustration of a source electrode 22 arranged on the top surface 12a of the semiconductor substrate 12.

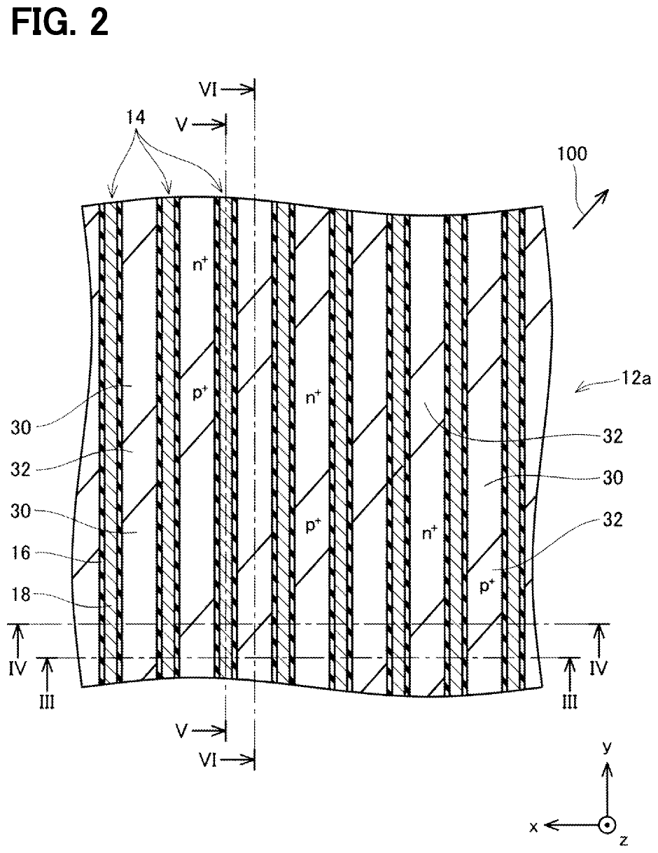

As illustrated in FIGS. 1, 2, multiple trenches 14 are disposed at the top surface 12a of the semiconductor substrate 12. The trenches 14 extend in the y-direction at the top surface 12a. The trenches 14 are arranged to be spaced apart in the x-direction.

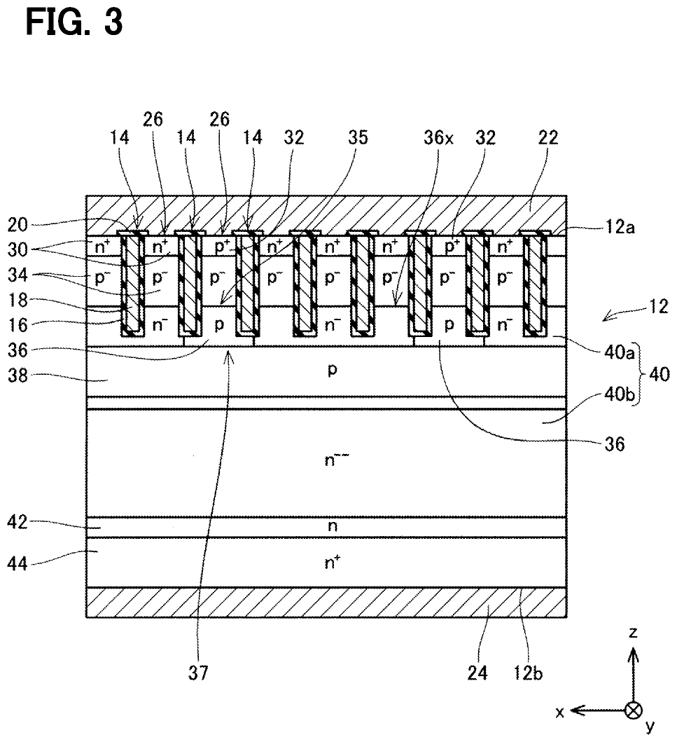

As shown in FIGS. 1 to 5, the inner surface of each of the trenches 14 is covered with a gate insulation film 16. The inner surface may also be referred to as a bottom surface and a side surface of each of the trenches 14. Agate electrode 18 is arranged in each of the trenches 14. The gate electrode 18 is insulated from the semiconductor substrate 12 through the gate insulation film 16. As shown in FIGS. 3 to 5, a top surface of the gate electrode 18 is covered with an interlayer insulation film 20.

As illustrated in FIGS. 3 to 6, the source electrode 22 is disposed at the top of the semiconductor substrate 12. The source electrode 22 covers the interlayer insulation film 20. The source electrode 22 is insulated from the gate electrodes 18 by the interlayer insulation film 20. The source electrode 22 is in contact with the top surface 12a of the semiconductor substrate 12 at a portion where the interlayer insulation film 20 is not provided. A drain electrode 24 is arranged at the bottom of the semiconductor substrate 12. The drain electrode 24 is in contact with the entire region of a bottom surface 12b of the semiconductor substrate 12.

As illustrated in FIGS. 1, 3, 4, the semiconductor substrate 12 includes inter-trench semiconductor regions 26 respectively sandwiched between the trenches 14. Each of the inter-trench semiconductor regions 26 extends in the y-direction along the trench 14. A source region 30, a contact region 32 and a body region 34 are provided in each of the inter-trench semiconductor region 26.

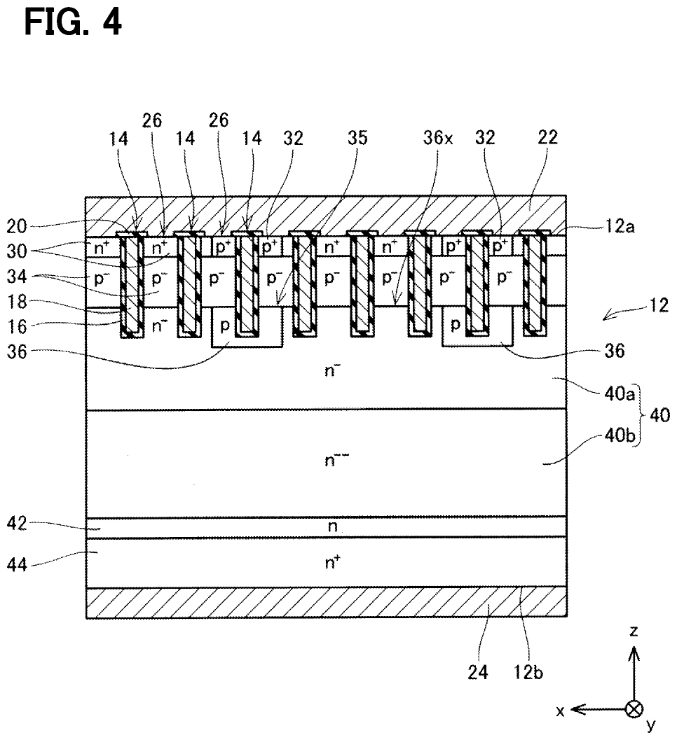

As shown in FIGS. 1 to 4, multiple source regions 30 and multiple contact regions 32 are provided at a region including the top surface 12a of the semiconductor substrate 12. Each of the source regions 30 is an n-type, and has relatively high n-type impurity concentration. Each of the contact regions 32 is a p-type region, and has relatively high p-type impurity concentration. As illustrated in FIGS. 3, 4, the source regions 30 and the contact regions 32 are in ohmic contact with the source electrode 22. As illustrated in FIGS. 1, 2, each of the source regions 30 and each of the contact regions 32 respectively have rectangular shapes in a direction 100 obliquely intersecting the lengthwise direction of each of the trenches 14, in other words, the y-direction. The source regions 30 and the contact regions 32 are alternately arranged in a direction perpendicular to the direction 100.

In other words, the contact regions 32 are arranged at intervals in a direction perpendicular to the direction 100, and extend in the direction 100 intersecting the y-direction in the top view of the semiconductor substrate 12 as illustrated in FIG. 2. The source regions 30 are arranged at intervals in a direction perpendicular to the direction 100, and extend in the direction 100 intersecting the y-direction in the top view of the semiconductor substrate 12 as illustrated in FIG. 2. The source region 30 is arranged between the contact regions 32, and the contact region 32 is arranged between the source regions 30. As illustrated in FIGS. 1, 3, each of the source regions 30 is in contact with the gate insulation film 16 at the uppermost part of the side surface of the trench 14. Each of the contact regions 32 is in contact with the gate insulation film 16 at the uppermost part of the side surface of the trench 14.

Each of the body regions 34 is a p-type region, and has lower p-type impurity concentration than the contact region 32. As illustrated in FIGS. 1, 3, 4, 6, the body regions 34 are arranged below the source regions 30 and the contact regions 32. In each of the inter-trench semiconductor region 26, each of the body regions 34 is distributed over the entire x-direction and y-direction. The body regions 34 are respectively in contact with the source regions 30 and the contact regions 32 below. Each of the body regions 34 is in contact with the gate insulation film 16 at the side surface of the trench 14 located below the source region 30 and the contact region 32.

As illustrated in FIGS. 3 to 6, the semiconductor substrate 12 includes multiple connection regions 36, multiple field relaxation regions 38, a drift region 40, a buffer region 42 and a drain region 44.

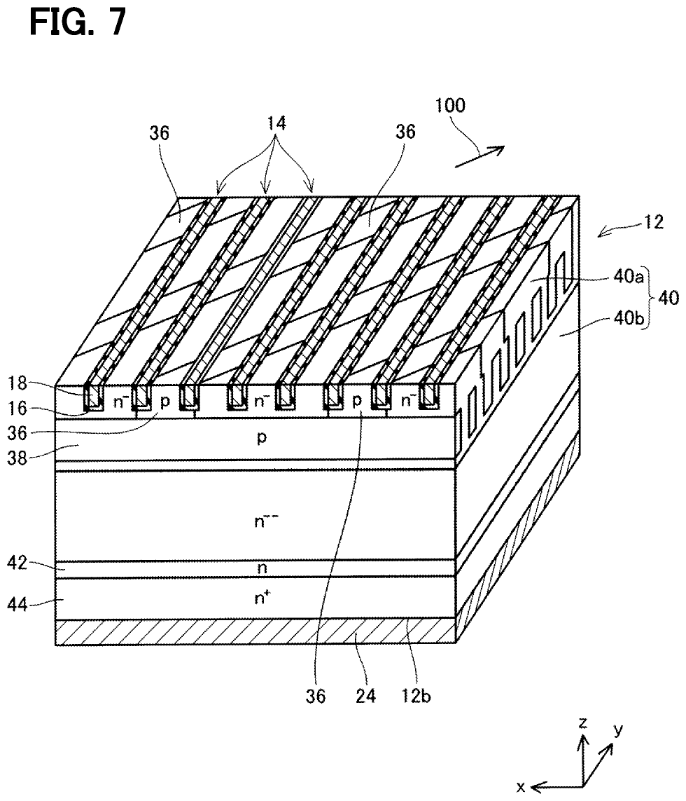

Each of the connection regions 36 is the p-type region, and has higher p-type impurity concentration than the body region 34. As shown in FIGS. 1, 3 to 6, the connection regions 36 are arranged below the body regions 34. As shown in FIG. 7, the connection regions 36 extends in the direction 100 obliquely intersecting the y-direction in the top view of the semiconductor substrate 12. The connection regions 36 are arranged at intervals in a direction perpendicular to the direction 100 in the top view of the semiconductor substrate 12. As illustrated in FIGS. 1, 3, each of the connection regions 36 is arranged immediately below the corresponding contact region 32. Therefore, each of the contact regions 32 extends in the direction 100 to overlap the corresponding connection region 36 in the top view of the semiconductor substrate 12. As shown in FIGS. 3, 4, and 6, the connection regions 36 are connected to the body regions 34 at intersecting portions 35 respectively intersecting with the body regions 34. The connection regions 36 extend downward from the bottom surface of each of the body regions 34 to a position lower than the bottom end of each of the body regions 34. Each of the connection regions 36 is in contact with the gate insulation film 16 at the side surface of the trench 14 located below the body regions 34.

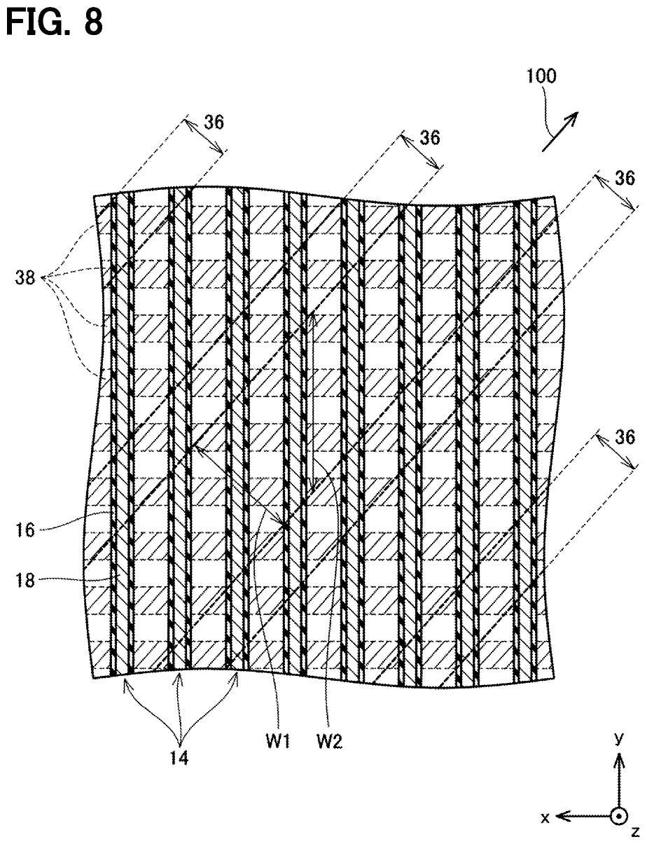

Each of the field relaxation regions 38 is the p-type region. Each of the field relaxation regions 38 has p-type impurity concentration higher than the body regions 34 but lower than the connection regions 36. As illustrated in FIGS. 1, 3, 5, 6, the field relaxation regions 38 is arranged below the connection region 36. As illustrated in FIGS. 1, 8, each of the field relaxation regions 38 includes an elongated shape in the x-direction. In other words, each of the field relaxation region 38 extends in the x-direction intersecting the y-direction and the direction 100 in the top view of the semiconductor substrate 12. The y-direction corresponds to the lengthwise direction of the trench 14, and the direction 100 corresponds to the lengthwise direction of the connection region 36. The field relaxation regions 38 are arranged at intervals in the y-direction perpendicular to the x-direction. As illustrated in FIGS. 3, 5, 6, a top end portion of each of the field relaxation regions 38 is arranged in a depth region overlapping a bottom end portion of the connection region 36. The field relaxation regions 38 are connected to the connection regions 36 at intersecting portions 37 respectively intersecting with the connection region 36. The field relaxation regions 38 are connected to the source electrode 22 through the connection regions 36, the body regions 34 and the contact regions 32.

The drift region 40 is the n-type. As illustrated in FIGS. 1, 3 to 6, the drift region 40 is distributed from a position in contact with the bottom surface of each of the body regions 34 to a position below the field relaxation regions 38. In other words, the drift region 40 is distributed in a spacing portion 36x between the connection regions 36, a spacing portion 38x between the field relaxation regions 38, and a region below the field relaxation regions 38. The drift region 40 is in contact with the bottom surface of the body region 34 in the spacing portion 36x between the connection regions 36. The drift region 40 inside the spacing portion 36x is in contact with the gate insulation film 16 at the side surface of the trench 14 and the bottom surface of the trench 14 located below the corresponding body region 34. The drift region 40 includes a high-concentration region 40a and a low-concentration region 40b. The n-type impurity concentration of the high-concentration region 40a is higher than the n-type impurity concentration of the low-concentration region 40b. In other words, the high-concentration region 40a is distributed in the spacing portion 36x between the connection regions 36, an spacing portion 38x between the field relaxation regions 38, and a region below the field relaxation regions 38. The low-concentration region 40b is arranged below the high-concentration region 40a. The low-concentration region 40b is contact with the high-concentration region 40a from below.

The buffer region 42 is the n-type, and has higher n-type impurity concentration than the low-concentration region 40b of the drift region 40. The buffer region 42 is in contact with the low-concentration region 40b as viewed from below.

The drain region 44 is the n-type, and has higher n-type impurity concentration than the buffer region 42. The drain region 44 is in contact with the buffer region 42 as viewed from below. The drain region 44 is arranged in a region including the bottom surface 12b of the semiconductor substrate 12. The drain region 44 is in ohmic contact with the drain electrode 24 at the bottom surface 12b.

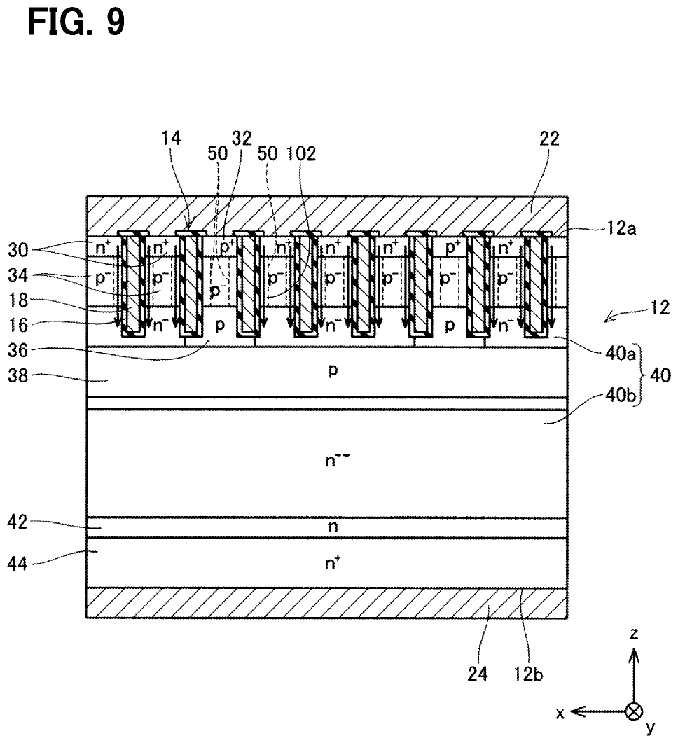

When the MOSFET 10 is used, a higher potential is applied to the drain electrode 24 as compared to the source electrode 22. When a potential higher than a threshold value is applied to the gate electrode 18, a channel 50 is formed in the body region 34 in the vicinity of the gate insulation film 16 as illustrated in FIG. 9. The channel 50 connects the source region 30 and the drift region 40. As illustrated by an arrow 102 in FIG. 9, electrons flow from the source region 30 to the drift region 40 through the channel 50. Therefore, the electrons flow from the source electrode 22 to the drain electrode 24 through the source region 30, the channel 50, the drift region 40, and the buffer region 42.

When the potential of each of the gate electrodes 18 is reduced from a value equal to or more than a gate threshold value to a value less than the gate threshold value, the channel 50 disappears and the flow of electrons stops. In other words, the MOSFET 10 is turned off. When the channel 50 disappears, the potential of the drift region 40 rises. On the other hand, since the body regions 34 are connected to the source electrode 22 through the contact regions 32, the potential of each of the body regions 34 is maintained at a potential substantially identical to the source electrode 22, in other words, a relatively low potential. When the channel 50 disappears, the pn junction of the boundary surface between the corresponding body region 34 and the drift region 40 is applied by a reverse voltage. Therefore, the depletion layer spreads into the drift region 40 from the body region 34. The field relaxation regions 38 are connected to the source electrode 22 through the connection regions 36, the body regions 34 and the contact regions 32. Therefore, the potential of each of the connection regions 36 is also maintained at a potential substantially identical to the source electrode 22, in other words, a relatively low potential. When the channel 50 disappears, the reverse voltage is applied to the pn junction of the boundary surface between the corresponding field relaxation region 38 and the drift region 40, and the depletion layer spreads into the drift region 40 from the corresponding field relaxation region 38. The depletion layer spreading from the corresponding field relaxation region 38 quickly depletes the drift region 40 around the bottom end of the trench 14. As a result, concentration of the electrical field around the bottom end of the trench 14 can be inhibited.

In the MOSFET 10 according to the present embodiment, as illustrated in FIG. 8, since each of the connection regions 36 extend in a direction intersecting the field relaxation regions 38, it is possible to ensure the connection of the field relaxation regions 38 to the body regions 34 through the connection regions 36. Therefore, the depletion layer easily spreads from the corresponding field relaxation region 38 to the drift region 40 to effectively suppress the concentration of electrical field at the bottom end of the corresponding trench 14.

In the MOSFET 10 according to the present embodiment, as illustrated in FIG. 8, since each of the connection regions 36 extends in a direction intersecting the trenches 14, it is possible to inhibit the concentration of electrical field when the MOSFET 10 is turned on. The following described the suppression of the concentration of electrical field. As illustrated in FIG. 9, in an overlapping portion where the connection region 36 overlaps the trench 14, since the connection region 36 is present below the body region 34, the channel 50 formed at the body region 34 is not connected to the drift region 40. Therefore, no current flows through the channel 50 in the overlapping portion where the connection region 36 overlaps the trench 14. In the present embodiment, as illustrated in FIG. 8, since each of the connection regions 36 extends in a direction intersecting the trenches 14, the overlapping portion where the connection region 36 overlaps the trench 14 is arranged to be scattered over the trenches 14. In other words, in the MOSFET 10 according to the present embodiment, there is no situation such that the entire side surface of a specific trench overlaps the connection region 136 as illustrated in FIGS. 15, 16. As illustrated in FIGS. 15, 16, when the entire side surface of the specific trench overlaps with the connection region 136, the current concentrates at the channel adjacent to the overlapping portion. In contrast, in the MOSFET 10 according to the present embodiment, as illustrated in FIG. 8, since the overlapping portion where the connection region 36 overlaps the trench 14 is scattered over the trenches 14, the region where the current does not flow is scattered, and the concentration of current does not easily occur. The overlapping portion corresponds to an intersecting portion. In the present embodiment, since each of the connection regions 36 obliquely intersects the trenches 14, the overlapping portion, in other words, the intersecting portion is scattered in the lengthwise direction of the trench 14. The MOSFET 10 according to the present embodiment suppresses the concentration of current. For this reason, the MOSFET according to the present embodiment has higher allowance amount of current that can be conducted.

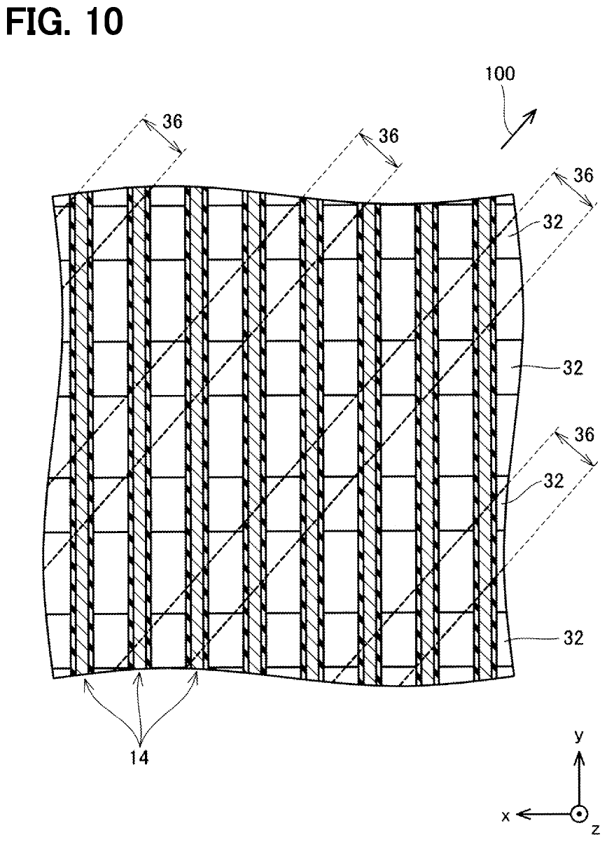

In the MOSFET 10 according to the present embodiment, each of the contact regions 32 is arranged at a position overlapping the corresponding connection region 36 in the top view of the semiconductor substrate 12. As a result, the on-resistance of the MOSFET 10 is reduced. The following describes the reduction of the on-resistance. As illustrated in FIG. 9, in an overlapping portion where the contact region 32 overlaps the trench 14, since the contact region 32 is present above the body region 34, the channel 50 formed at the body region 34 is not connected to the source region 30. Therefore, no current flows through the channel 50 in the overlapping portion where the contact region 32 overlaps the trench 14. As in the MOSFET according to the comparative example illustrated in FIG. 10, when the connection region 36 and the contact region 32 respectively extend in different directions, the overlapping portion where the contact region 32 overlaps the trench 14 and the overlapping portion where the connection region 36 overlaps the trench 14 are formed at different positions. Each of the overlapping portions described above correspond to a portion where the current does not flow through the channel. For this reason, the region where the current can flow is narrow. In contrast, in the MOSFET 10 according to the present embodiment, the contact region 32 and the connection region 36 extend in the direction 100 in the overlapping state. In the top view of the semiconductor substrate 12, a position of the intersecting portion where the contact region 32 intersects the trench 14 substantially coincides with the position of the intersecting portion where the connection region 36 intersects the trench 14. Therefore, it is possible to ensure a wider region where the current can flow. As a result, the MOSFET 10 according to the present embodiment has relatively low on-resistance.

In the MOSFET 10 according to the present embodiment, each of the connection regions 36 obliquely intersects the trench 14. As illustrated in FIG. 8, spacing W1 between the connection regions 36 is narrower than spacing W2 between the connection regions 36 in a direction along the trench 14. When a higher voltage is applied to the MOSFET 10 at the off state, the depletion layer spreads from the corresponding connection region 36 to the drift region 40 around the connection region 36, and the voltage is maintained through the depletion layer. Since the spacing W1 is narrow, the drift region 40 inside the region of the spacing W1 is easily depleted by the depletion layer spreading from the corresponding connection region 36. According to the above-mentioned structure, it is possible to enhance the breakdown voltage, in other words, the withstand voltage of the MOSFET 10. When the spacing W2 in a direction along the trench 14 is ensured to be wider, it is possible to ensure to have a wider region (in other words, the trench 14 in a region not overlapping the connection region 36) where the current can flow through the channel. As a result, it is possible to reduce the on-resistance of the MOSFET. As described above, according to this structure, it is possible to have a higher breakdown voltage and lower on-resistance.

The following describes a method of manufacturing the MOSFET 10 according to the present embodiment. Since this manufacturing method has features in the formation of the contact region 32 and the formation of the connection region 36, the following describes the formation of both of the contact region 32 and the connection region 36.

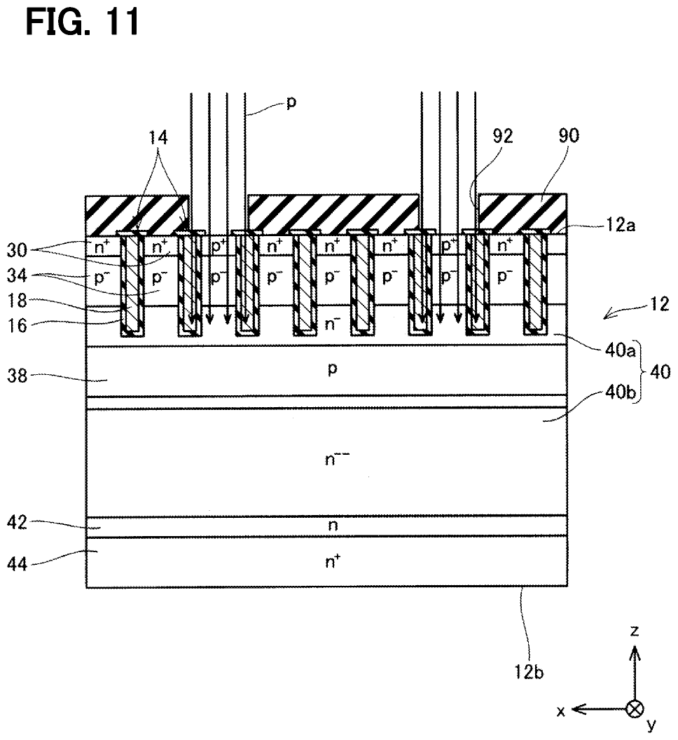

In the formation of both of the contact region 32 and the connection region 36, as illustrated in FIG. 11, a mask 90 is formed on the top surface 12a of the semiconductor substrate 12. The mask 90 is formed to locate an aperture 92 at a top portion of a region corresponding to the contact region 32 and the connection region 36. Then, p-type impurity ions are implanted into the semiconductor substrate 12 through the mask 90. By changing ion-implantation energy, the p-type impurities are injected into a depth region of the connection region 36 and a depth region of the contact region 32. Subsequently, by performing activation annealing of impurities, the connection region 36 and the contact region 32 are formed. In this manufacturing method, it is possible to form the connection region 36 and the contact region 32 through ion-implantation by using the common mask 90. As a result, it is possible to efficiently manufacture the MOSFET 10.

### First Modification

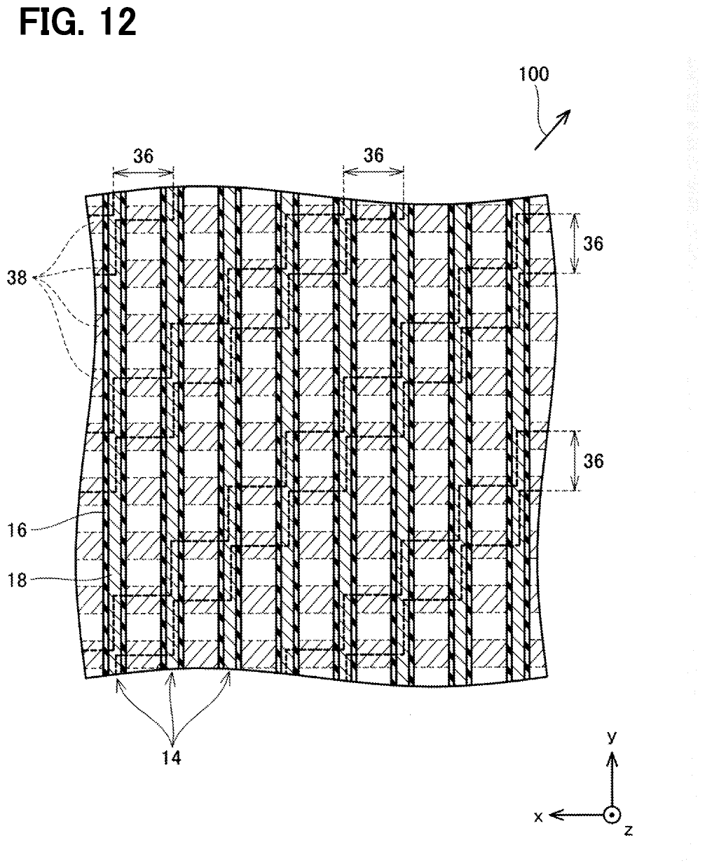

In the MOSFET 10 according to the above mentioned embodiment, the side surface of each of the connection regions 36 extends in a linear shape in the direction 100. For example, in a first modification of the present disclosure, the side surface of each of the connection regions 36 may extend while bending in the direction 100, as illustrated in FIG. 12. However, in a region closer to the limit of semiconductor processing precision, in particular, pattern exposure precision, when the connection region 36 is formed to have a side surface curved as illustrated in FIG. 12, the difference in respective shapes of the connection regions becomes larger. In contrast, the side surface of each of the connection regions 36 extends in a linear shape in the direction 100 as illustrated in FIG. 8, it is possible to form each of the connection regions 36 with higher precision, and it is possible to suppress the differences in the characteristics of the MOSFET 10.

### Second Modification

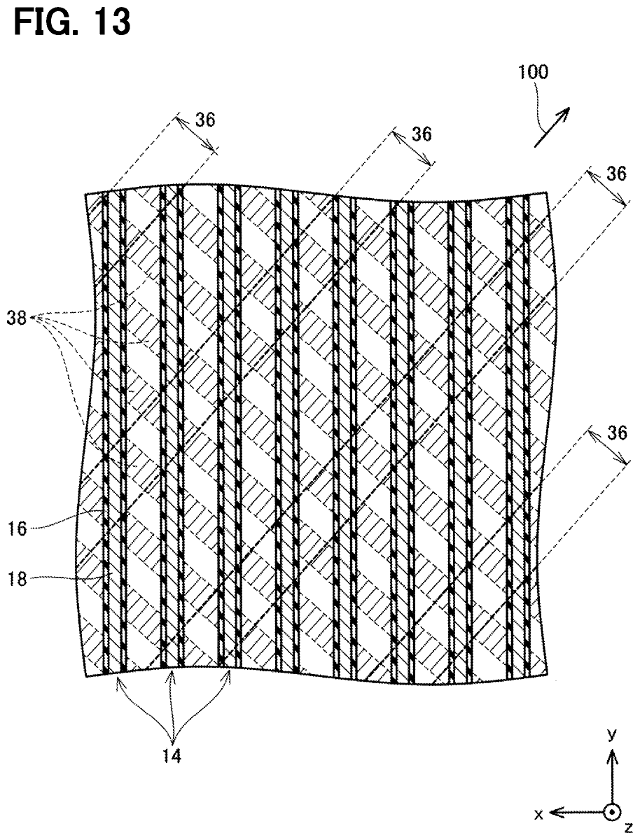

In the above-mentioned embodiment, as illustrated in FIG. 8, in the top view of the semiconductor substrate 12, the field relaxation region 38 extends in a direction perpendicular to the trench 14. However, as illustrated in FIG. 13, the field relaxation region 38 may extend in a direction obliquely intersecting the trench 14 in a second modification of the present disclosure.

### Third Modification

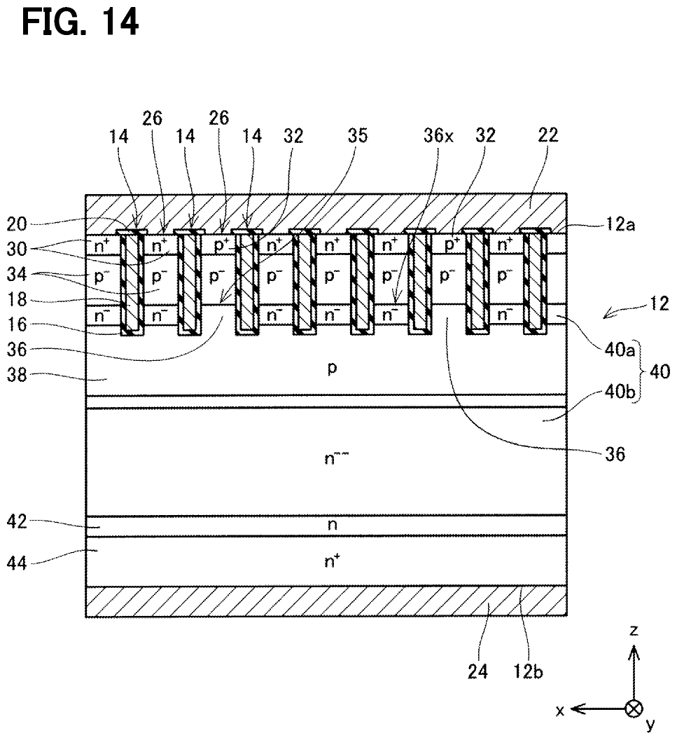

In the above-mentioned embodiment, the spacing is provided between the field relaxation region 38 and the bottom end of the trench 14, as illustrated in FIG. 3. However, the field relaxation region 38 may be in contact with the bottom end of the trench 14 in a third modification of the present disclosure, as illustrated in FIG. 14.

The y-direction described in this embodiment corresponds to a first direction. The direction 100 described in this embodiment corresponds to a second direction. The x-direction described in this embodiment corresponds to a third direction.

In the field effect transistor described in the present disclosure, each of contact regions may extend in the second direction to overlap corresponding one of connection regions in a top view of a semiconductor substrate.

When the field effect transistor is turned on, a channel is not connected to a source electrode and a current does not flow at a portion where each of the contact regions intersects each of the trenches. As each of the contact regions overlaps the corresponding connection region, the portion where the current does not flow lies on top of one another. In other words, the intersecting portion where the connection region intersects the trench and the intersecting portion where the corresponding contact region intersects the corresponding trench overlap each other. Therefore, it is possible to reduce the area where the current does not flow. Therefore, it is possible reduce on-resistance of the field effect transistor.

In the field effect transistor described in the present disclosure, the second direction may intersect obliquely with respect to a first direction.

According to the above-mentioned structure, the intersecting portions where the connection regions respectively intersect the trenches are scattered along a lengthwise direction of the trenches. The lengthwise direction corresponds to the first direction. Therefore, it is possible to effectively relieve the current concentration.

In the field effect transistor described in the present disclosure, each of the connection regions has a side surface with a linear shape that may extend in the second direction.

As a result, it is possible to stabilize the characteristics of the field effect transistor.

Although the embodiments have been described in detail above, these are merely examples and do not limit the scope of present disclosure. The techniques described in the present disclosure include various modifications and modifications of the specific examples illustrated above. The technical elements described in the present disclosure or the drawings exhibit technical usefulness alone or in various combinations, and are not limited to the combinations described in the present disclosure at the time of filing. In addition, the techniques illustrated in the present specification or drawings achieve multiple objectives at the same time, and achieving one of the objectives itself has technical usefulness.

What is claimed is:

1. Afield effect transistor comprising:
a semiconductor substrate;
a plurality of trenches disposed at a top surface of the semiconductor substrate;
a gate insulation film disposed in each of the trenches;
a gate electrode disposed in each of the trenches; and
a source electrode covering the top surface of the semiconductor substrate,
wherein the trenches respectively extend in a first direction at the top surface, and the trenches are spaced part in a direction perpendicular to the first direction,
wherein the semiconductor substrate includes a plurality of inter-trench semiconductor regions, and each of the inter-trench semiconductor regions is disposed between adjacent two of the trenches,
wherein the inter-trench semiconductor regions respectively include a plurality of source regions, a plurality of contact regions, and a plurality of body regions,
wherein each of the source regions is an n-type and is in contact with the source electrode and the gate insulation film,
wherein each of the contact regions is a p-type and is in contact with the source electrode,
wherein each of the body regions is the p-type and has lower p-type impurity concentration than each of the contact regions,
wherein each of the body regions is in contact with the gate insulation film at a side closer to a bottom surface of the semiconductor substrate than the source regions, and is in contact with corresponding one of the contact regions and corresponding one of the source regions at a side closer to the bottom surface of the semiconductor substrate than the contact regions and the source regions,
wherein the semiconductor substrate further includes:
a plurality of connection regions, each of which is the p-type;
a plurality of field relaxation regions, each of which is the p-type; and
a drift region being the n-type,
wherein the connection regions are disposed at a side closer to the bottom surface of the semiconductor substrate than the body regions,
wherein the connection regions respectively extend in a second direction intersecting the first direction in a top view of the semiconductor substrate, and are disposed to be spaced apart in a direction perpendicular to the second direction in the top view of the semiconductor substrate,
wherein the connection regions are connected to the body regions at intersecting portions where the connection regions respectively intersect the body regions,
wherein the field relaxation regions are disposed at a side closer to the bottom surface of the semiconductor substrate than the connection regions and the trenches,
wherein the field relaxation regions extend in a third direction intersecting the first direction and the second direction in the top view of the semiconductor substrate, and are disposed to be spaced apart in a direction perpendicular to the third direction in the top view of the semiconductor substrate,
wherein the field relaxation regions are connected to the connection regions at intersecting portions where the field relaxation regions respectively intersect the connection regions,
wherein the drift region is disposed at a first spacing portion between adjacent two of the connection regions, a second spacing portion between adjacent two of the field relaxation regions, and a location closer to the bottom surface of the semiconductor substrate than the field relaxation regions, and
wherein the drift region is in contact with the body regions at a side closer to the bottom surface of the semiconductor substrate than the body regions, and is in contact with the gate insulation film at a side closer to the bottom surface of the semiconductor substrate than the gate insulation film.

2. The field effect transistor according to claim 1,
wherein each of the contact regions extends in the second direction to overlap corresponding one of the connection regions in the top view of the semiconductor substrate.

3. The field effect transistor according to claim 1,
wherein the second direction obliquely intersects the first direction.

4. The field effect transistor according to claim 1,
wherein each of the connection regions has a side surface with a linear shape extending in the second direction.

5. A method of manufacturing a field effect transistor, the method comprising:
injecting p-type impurities to a plurality of contact regions of a semiconductor substrate and a plurality of connection regions of the semiconductor substrate through a common mask,
wherein the field effect transistor includes:
the semiconductor substrate;
a plurality of trenches disposed at a top surface of the semiconductor substrate;
a gate insulation film disposed in each of the trenches;
a gate electrode disposed in each of the trenches; and
a source electrode covering the top surface of the semiconductor substrate,
wherein the trenches respectively extend in a first direction at the top surface, and the trenches are spaced part in a direction perpendicular to the first direction,
wherein the semiconductor substrate includes a plurality of inter-trench semiconductor regions, and each of the inter-trench semiconductor regions is disposed between adjacent two of the trenches,
wherein the inter-trench semiconductor regions respectively include a plurality of source regions, the contact regions, and a plurality of body regions,
wherein each of the source regions is an n-type and is in contact with the source electrode and the gate insulation film,
wherein each of the contact regions is a p-type and is in contact with the source electrode,
wherein each of the body regions is the p-type and has lower p-type impurity concentration than each of the contact regions,
wherein each of the body regions is in contact with the gate insulation film at a side closer to a bottom surface of the semiconductor substrate than the source regions, and is in contact with corresponding one of the contact regions and corresponding one of the source regions at a side closer to the bottom surface of the semiconductor substrate than the contact regions and the source regions,
wherein the semiconductor substrate further includes:
the connection regions, each of which is the p-type;
a plurality of field relaxation regions, each of which is the p-type; and
a drift region being the n-type,
wherein the connection regions are disposed at a side closer to the bottom surface of the semiconductor substrate than the body regions,
wherein the connection regions respectively extend in a second direction intersecting the first direction in a top view of the semiconductor substrate, and are disposed to be spaced apart in a direction perpendicular to the second direction in the top view of the semiconductor substrate,
wherein the connection regions are connected to the body regions at intersecting portions where the connection regions respectively intersect the body regions,
wherein the field relaxation regions are disposed at a side closer to the bottom surface of the semiconductor substrate than the connection regions and the trenches,
wherein the field relaxation regions extend in a third direction intersecting the first direction and the second direction in the top view of the semiconductor substrate, and are disposed to be spaced apart in a direction perpendicular to the third direction in the top view of the semiconductor substrate,
wherein the field relaxation regions are connected to the connection regions at intersecting portions where the field relaxation regions respectively intersect the connection regions,
wherein the drift region is disposed at a first spacing portion between adjacent two of the connection regions, a second spacing portion between adjacent two of the field relaxation regions, and a location at a side closer to the bottom surface of the semiconductor substrate than the field relaxation regions, and
wherein the drift region is in contact with the body regions at a side closer to the bottom surface of the semiconductor substrate than the body regions, and is in contact with the gate insulation film at a side closer to the bottom surface of the semiconductor substrate than the gate insulation film.
